(19) United States
(12) Patent Application Publication
(10) Pub. No.: US 2006/0097409 A1
(43) Pub. Date: May 11, 2006

(54) Semiconductor device

(75) Inventors: Toshiaki Shironouchi, Kawasaki (JP); Fumiaki Kishida, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/266,351

(22) Filed: Nov. 4, 2005

(30) Foreign Application Priority Data
Nov. 10, 2004 (JP) 2004-326270

(51) Int. Cl. H01L 23/29

(52) U.S. Cl. 257/789

(57) ABSTRACT

In a semiconductor device, an average grain size of a filler contained in an adhesive agent applied to the first chip is larger than an interval between adjacent wires. When the second chip is pressed downward, the filler is caught between the wires, a larger number of filler grains is held between the first and second chip. The interval between the first and the second chip can be stably maintained. Since the number of filler grains left to be held between the first and second chip is larger than that in the conventional art, a pressure applied to the second chip is uniformly distributed while suppressing the number of filler grains contained in the adhesive agent from increasing, and a pressure applied to the grains is lower than that in the conventional art.

This application is based on Japanese Patent application NO. 2004-326270, the content of which is incorporated hereinto by reference.

### BACKGROUND

1. Technical Field

The present invention relates to a chip-stack-type semiconductor device.

2. Related Art

In a chip-stack-type semiconductor device on which a first chip and a second chip are sequentially stacked, the sizes of these chips may approximate to each other, or the size of the second chip may be larger than the size of the first chip. In these cases, since the second chip is located above a bonding wire for connecting the first chip and a substrate, it must be considered that the bonding wire is not in contact with the second semiconductor chip. For this reason, a semiconductor device having a spacer structure in which a dummy chip or an elastomer having a size slightly smaller than the first chip is sandwiched between the first chip and the second chip to keep insulation by assuring a clearance of the bonding wire has been manufactured.

However, these spacer structures were the obstructions of the cost reduction because material cost of the spacer is excessively high and cost of processing is extra necessary.

Therefore, a chip-stack-type semiconductor device that uses the adhesive including filler having a uniform grain size to suppress contact between a first chip and a second chip is proposed in Japanese Laid-open patent publication NO. H10-256470.

It is an object of Japanese Laid-open patent publication NO. H10-256470 to suppress contact between chips. For this reason, in Japanese Laid-open patent publication NO. H10-256470, grain sizes of a filler used in a spacer-filler-contained adhesive agent range from 1 to 50 μm or 20 to 40 μm. Japanese Laid-open patent publication NO. H10-256470 describes the following steps though a detailed drawing has not been described. That is, a predetermined amount of an insulating paste second adhesive agent is supplied onto a first semiconductor chip, a second semiconductor chip adsorbed by a vacuum collet is moved onto a first semiconductor chip and positioned, and the second semiconductor chip is pressed on the first semiconductor chip at a predetermined pressure to cause the second adhesive agent to uniformly spread.

However, when an adhesive agent containing a spacer filler is used to assure a clearance of a bonding wire, it is difficult to suppress contact between the bonding wire and a second chip. This is because, when the second chip is to be stacked on a first chip, a gap between the first chip and the second chip must be larger than not more than the diameter of the bonding wire.

An interval between adjacent bonding wires depends on an interval of bonding pads formed on a first chip and the diameter of the bonding wire. For example, when a bonding wire having a diameter of 30 μm is used for bonding pads formed at a pitch of 100 μm, a distance between the adjacent bonding wires is 70 μm. For this reason, as shown in FIGS. 5 and 6, when a size of a filler 6 relative to a distance between adjacent bonding wires 4 is not regulated, a grain size of the filler 6 may be smaller than the distance between the bonding wires 4. In this case, with an increase in wet area of an adhesive agent 5 used when a second chip 7 is stacked, the filler 6 flows into a peripheral portion of a first chip 2 and then flows out of a chip region through a gap between the bonding wires 4.

In this case, since the adhesive agent 5 containing the spacer filler is necessary to keep viscosity thereof and physical characteristics thereof after hardening desired value, it is difficult to make the filler content extremely high. For this reason, when the filler 6 flows out of the chip region, the number of grains of the filler 6 left on a gap between the first chip 2 and the second chip 7 decreases, a stable clearance cannot be easily assured by the filler. When the number of gains of the filler 6 left on the gap between the first chip 2 and the second chip 7 decreases, a pressure at which the second chip 7 is stacked is concentrated on specific grains of the filler. Therefore a circuit forming surface of the first chip 2 may be damaged.

### SUMMARY OF THE INVENTION

According to the present invention, there is provided a semiconductor device including a substrate on which bonding pads are formed, a first element having a plurality of electrodes stacked on the substrate, and a second element stacked on the first element, wherein the bonding pads formed on the substrate and the first element are connected to each other by bonding using wires, an adhesive layer containing a filler is formed between the first element and the second element, and an average grain size of the filler is larger than a distance between the adjacent wires formed on the first element.

According to the present invention, the average grain size of the filler contained in the adhesive layer between the first element and the second element is relatively larger than a distance between adjacent wires connected to the first element. For this reason, contact between the first element and the second element can be suppressed, and the filler can be suppressed from passing through a gap between the wires. Therefore, a high-quality semiconductor device can be provided.

According to the present invention, the first and second elements can be suppressed from being in contact with each other, and the filler can be suppressed from passing through a gap between the wires, so that a high-quality semiconductor device is provided.

### BRIEF DESCRIPTION OF THE DRAWINGS

The above and other objects, advantages and features of the present invention will be more apparent from the following description taken in conjunction with the accompanying drawings, in which:

FIGS. 1A and 1B are diagrams typically showing a semiconductor device according to an embodiment of the present invention.

FIGS. 2A and 2B are diagrams typically showing a semiconductor device according to the embodiment of the present invention.

FIGS. 3A and 3B are diagrams typically showing a semiconductor device according to another embodiment of the present invention.

FIGS. 4A and 4B are diagrams typically showing a semiconductor device according to the embodiment of the present invention.

FIGS. 5A and 5B are diagrams typically showing a semiconductor device according to the embodiment of the conventional semiconductor device.

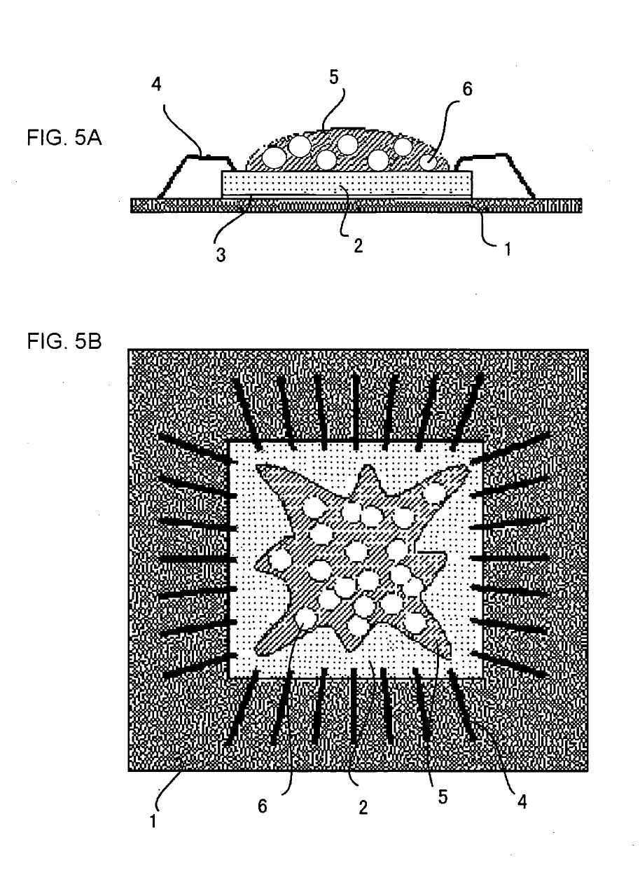

FIGS. 6A and 6B are diagrams typically showing a conventional semiconductor device.

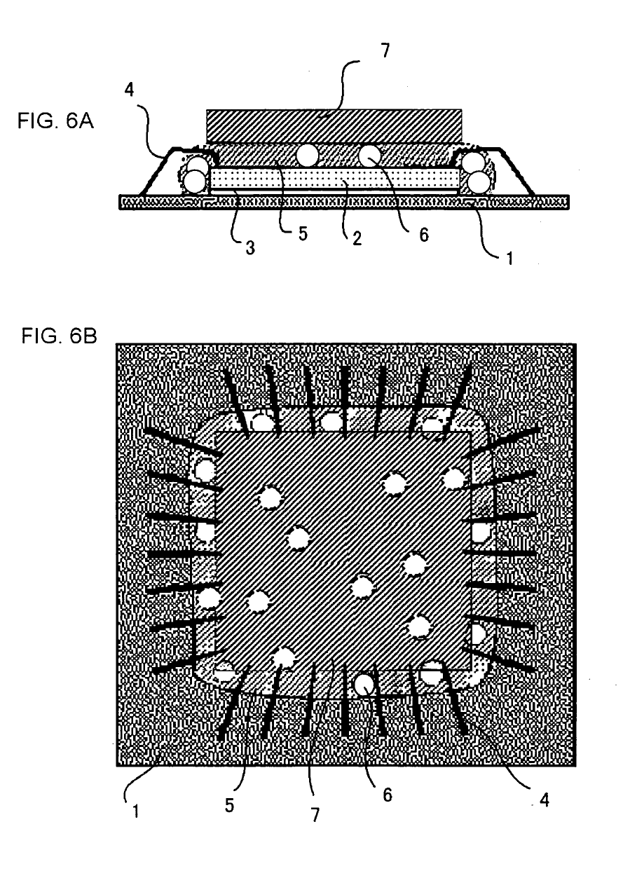

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments of the present invention will be described below with reference to the accompanying drawings. The same reference numerals as in all the drawings denote the same parts in the drawings, and explanations will not be properly described.

### FIRST EMBODIMENT

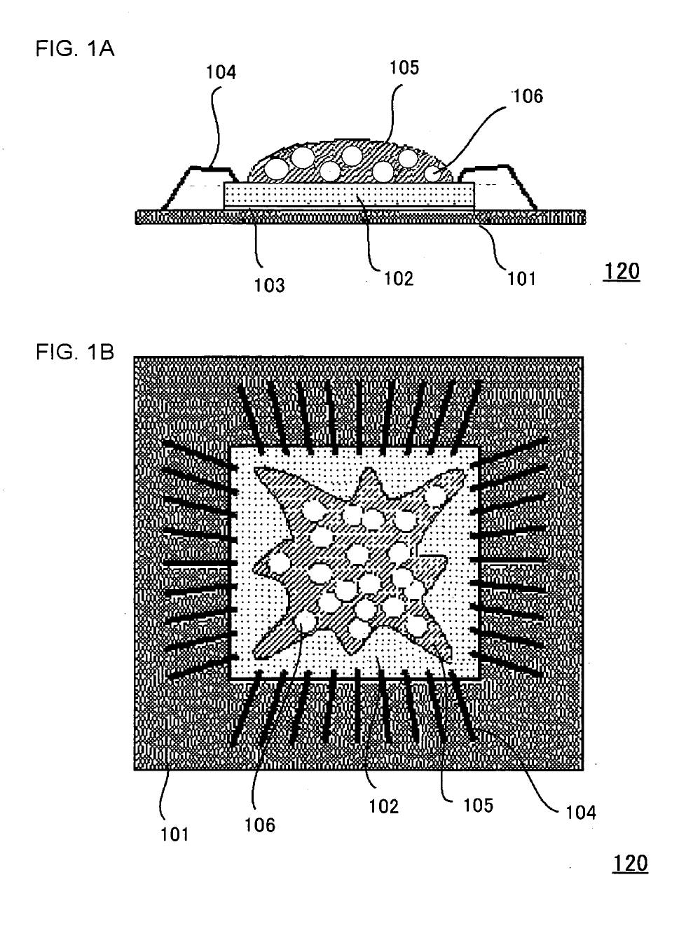

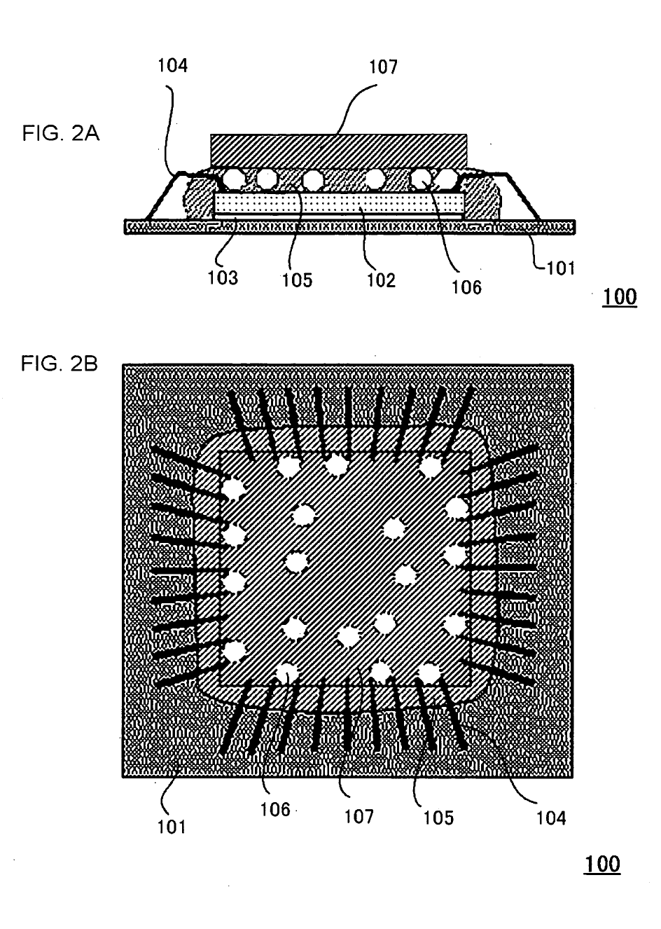

A semiconductor device shown in FIGS. 1A and 1B and FIGS. 2A and 2B includes an interconnect substrate 101 serving as a substrate on which bonding pads are formed, a first chip 102 serving as a first element having a plurality of pads as electrodes stacked on the interconnect substrate 101, and a second chip 107 serving as a second element stacked on the first chip 102. The bonding pads formed on the interconnect substrate 101 are connected to the first chip 102 by bonding using wires 104. The second chip 107 is located immediately above at least some of the plurality of pads formed on the first chip 102. An adhesive layer containing a filler 106 is formed between the first chip 102 and the second chip 107. An average grain size of the filler 106 is larger than a distance between the adjacent wires 104 formed on the first chip 102.

FIGS. 1A and 1B show a semiconductor device 120 to which an adhesive agent is applied according to the embodiment of the present invention, and FIGS. 2A and 2B show a semiconductor device 100 on which the second chip 107 is mounted according to the embodiment of the present invention.

As shown in FIGS. 1A and 1B, the first chip 102 is stacked on the interconnect substrate 101 through a paste adhesive agent 103. A plurality of pads (not shown) for bonding connection are formed on the first chip 102 at almost equal intervals of 100 μm.

The interconnect substrate 101 is a substrate to which the parts except the a copper interconnect portion are covered with an insulating material such as a solder resist. On the interconnect substrate 101, bonding pads (not shown) used in wire-bonding connection to the first chip 102 are formed on the insulating material.

The adhesive agent 103 may be an adhesive agent which can cause the interconnect substrate 101 to adhere to the first chip 102.

The interconnect substrate 101 and the first chip 102 are electrically connected to each other by using the wires 104.

As a material constituting the wires 104, a material such as gold having a high conductivity is used. The wires 104 are arranged by using a wire bonding device.

In the embodiment, the wires 104 are arranged on the first chip 102 at almost equal intervals of 100 μm. A diameter of the wire 104 is 30 μm. For this reason, a distance between the adjacent wires 104 is 70 μm.

As an example of the first chip 102, for example, a semiconductor element such as a transistor or an IC chip is known. In FIG. 1A, the upper surface of the first chip 102 corresponds to a circuit forming surface.

The paste adhesive agent 105, as shown in FIG. 1B, is applied on the first chip 102 such that the adhesive agent 105 radially spreads from a position near the center of the first chip 102 to the peripheral portion of the first chip 102.

An adhesive agent 105 has a function of causing the first chip 102 and the second chip 107 to adhere to each other. The adhesive agent 105 contains the filler 106, and also functions as a spacer which makes a space between the first chip 102 and the second chip 107 (to be described later). As a base material mainly constituting the adhesive agent 105, for example, an epoxy resin or the like is used.

In the embodiment, as the filler 106, for example, an insulating filler such as a filler having a high degree of elasticity including silica or a filler having a low degree of elasticity including silicon is used. The average grain size of the filler is 80 μm. Since the filler described above has a small coefficient of linear expansion, an adhesive layer obtained by hardening the adhesive agent 105 can be stably formed.

The grain sizes of the filler 106 are measured by gauging a cross section of the adhesive agent containing the filler by using a microscope. In the embodiment, a grain size distribution of the filler 106 falls within a range of ±10% of the average grain size.

As a shape of each grain of the filler 106, a shape such as an almost spherical shape is preferably used. When the shape of each grain of the filler 106 is almost spherical, the uniformity of the surface of the adhesive agent 105 can be more improved regardless of directions of the grains of the filler, and an interval between the first chip 102 and the second chip 107 can be stably maintained.

The average grain size of the filler 106 preferably falls within the range of more than 100% and 130% or less of the distance between the adjacent wires 104. The average grain size more preferably falls within the range of more than 110% and 120% or less. When the grain size falls within the range more than 100% and 130% or less, the possibility that the filler 106 passes through the gap between the wires 104 is reduced, and the interval between the first chip 102 and the second chip 107 can be set within an appropriate range. When the grain size falls within the range of more than 110% and 120% or less, the possibility that the filler 106 passes through the gap between the wires 104 is further reduced, and the interval between the first chip 102 and the second chip 107 can be set within a more appropriate range.

Furthermore, the average grain size of the filler 106 is larger than the diameter of the wire 104. In this manner, even though the second chip 107 is located immediately above at least some of the plurality of pads formed on the first chip 102, the wires 104 and the second chip 107 can be suppressed from being in contact with each other.

The adhesive agent 105 preferably contains about 0.1 wt % to 20 wt % of the filler 106. In the embodiment, the adhesive agent 105 contains about 1 wt % of the filler 106.

As shown in FIGS. 2A and 2B, the second chip 107 is pressed from the top of the adhesive agent 105 which is applied to the first chip 102 to the bottom of the adhesive agent 105. At this time, the adhesive agent 105 is caused to uniformly spread toward the peripheral portion of the first chip 102 as a whole. The adhesive agent 105 is filled between the first chip 102 and the second chip 107 such that a gap is rarely formed. In this case, as shown in FIGS. 2A and 2B, the excessive adhesive agent 105 which is not filled between the first chip 102 and the second chip 107 may run out of the peripheral portion of the first chip 102 to cover a side surface of the first chip 102. The adhesive agent 105 is hardened to be an adhesive layer.

As an example of the second chip 107, a semiconductor chip such as a transistor or an IC chip is used.

Effects of the semiconductor device 100 according to the embodiment will be described below.

In the semiconductor device 100, an average grain size of the filler 106 contained in the adhesive agent 105 applied to the first chip 102 is larger than an interval between the adjacent wires 104. For this reason, when the second chip 107 is pressed downward, the filler 106 is caught between the wires 104, and filler grains the number of which is larger than that of grains caught between wires in a conventional art are held between the first chip 102 and the second chip 107. Therefore, the interval between the first chip 102 and the second chip 107 can be stably maintained. The number of grains of the filler 106 contained in the adhesive agent between the first chip 102 and the second chip 107 is larger than that in the conventional art. For this reason, the number of grains of the filler 106 contained in the adhesive agent 105 applied to the first chip 102 need not be equal to or larger than that in the conventional art. Furthermore, a pressure applied to the second chip 107 are uniformly distributed to make a pressure applied to the filler 106 lower than that in the conventional art.

### SECOND EMBODIMENT

A semiconductor device which will be described in this embodiment uses a sheet-like adhesive agent as an adhesive agent 105. The sheet-like adhesive agent is stuck on the lower surface of a second chip 107 in advance and cause a first chip 102 to adhere to the second chip 107 by a heating/pressure-bonding method. The present embodiment is different from the first embodiment in these points.

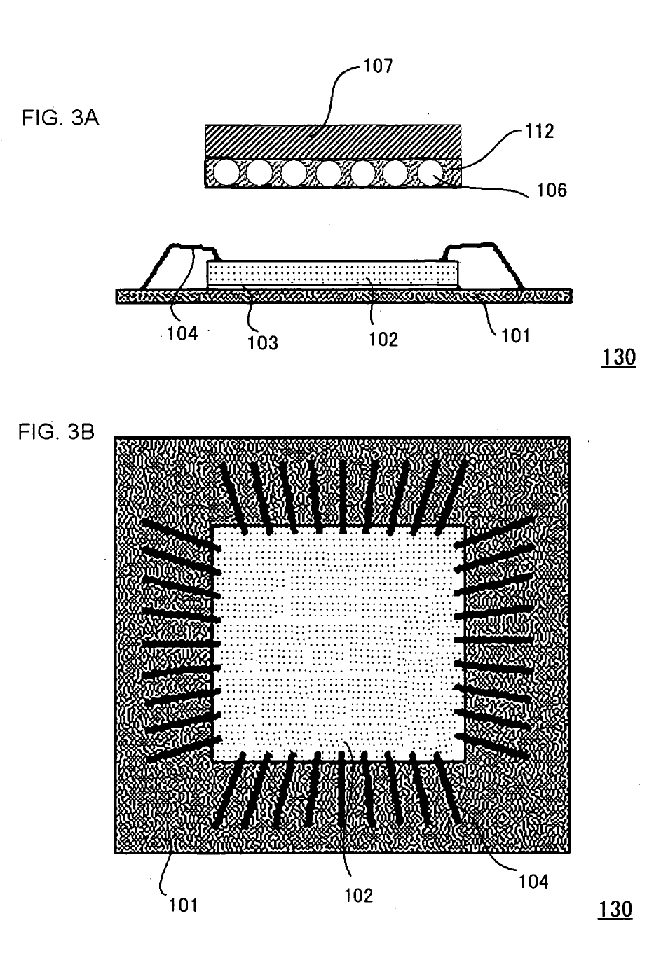

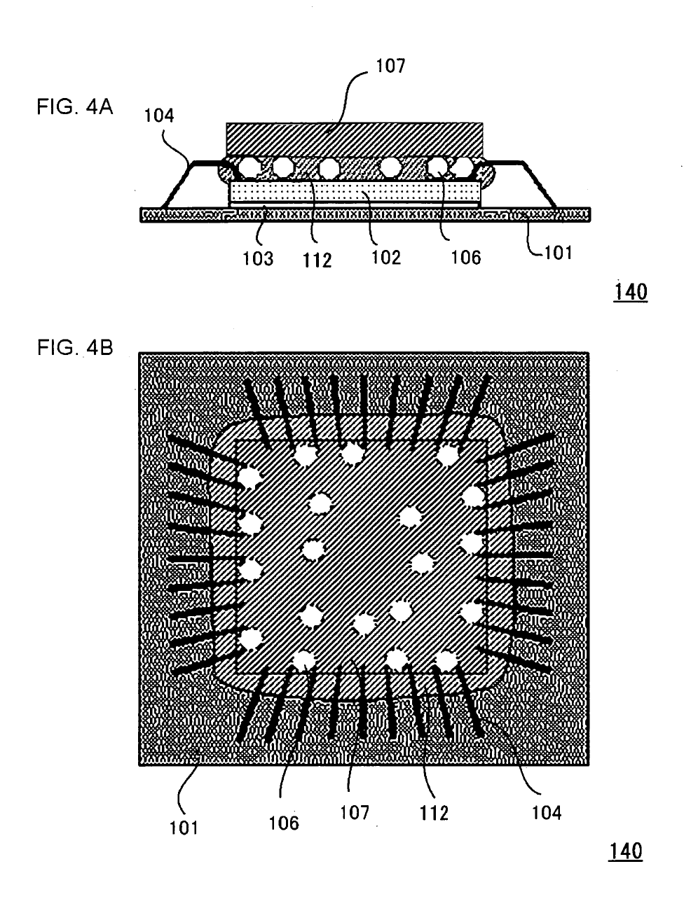

FIGS. 3A and 3B show a semiconductor device 130, and FIGS. 4A and 4B show a semiconductor device 140 on which the second chip 107 according to the embodiment is mounted.

In the semiconductor device 130 according to the embodiment, as shown in FIG. 3A, a sheet-like adhesive agent 112 is stuck on a rear surface (lower surface) of the second chip 107 in advance.

The sheet-like adhesive agent 112 contains a filler 106. The average grain size of the filler 106 is 80 μm as in the fist embodiment. As a base material mainly constituting the sheet-like adhesive agent 112, a B-stage epoxy resin or the like is used.

As shown in FIG. 4, when the second chip 107 is to be mounted on the first chip 102, the sheet-like adhesive agent 112 is heated and pressure-bonded to cause the first chip 102 to adhere to the second chip 107. In this manner, the semiconductor device 140 is completed.

Effects of the semiconductor device 140 according to the embodiment will be described below.

In the semiconductor device 140, the filler 106 is contained in the sheet-like adhesive agent 112. In this case, the average grain size of the filler 106 is larger than 70 μm which is a distance between adjacent wires 104 connected to the first chip 102 as in the first embodiment. Since the filler 106 is contained in the sheet-like adhesive agent 112, the fluidity of the filler 106 is more suppressed. Therefore, when the first chip 102 is adhered to the second chip, in the filler 106, the fluidity of the first chip 102 and the second chip 107 outward is further suppressed. Consequently, the interval between the first chip 102 and the second chip 107 can be more stably maintained. A pressure applied to the sheet-like adhesive agent 112 containing the filler 106 is more uniformly distributed to make it possible to more effectively reduce pressures applied to the respective grains of the filler 106.

The embodiments of the present invention have been described above with reference to the accompanying drawings. The embodiments are only exemplifications of the present invention, and various configurations other than the above configurations can also be employed.

For example, in the explanations of the embodiments, the first chip 102 and the second chip 107 are sequentially stacked on the interconnect substrate 101. However, three or more elements may be stacked. In this case, it is merely desired that an average grain size of the filler is larger than a distance between adjacent wires arranged on a lower semiconductor element of two semiconductor adjacent elements. When a distance between a third chip and a fourth chip being contact with each other is used as an example, it is merely desired that an average grain size of a filler contained in an adhesive layer which causes the third chip to adhere to the fourth chip is larger than an interval between wires connected to the third chip located in the lower portion.

In the embodiment, the average grain size of the filler 106 is 80 μm. However, when the average grain size is larger than the interval between the wires 104 connected to the first chip 102, the effects explained in the embodiments can be achieved. For example, when the interval between the wires 104 is 70 μm explained in the embodiments, the average grain size of the filler is made larger than 70 μm to make it possible to achieve the effects of the embodiments.

In the explanations of the embodiments, a semiconductor element such as a transistor or an IC chip is used as the second chip 107. However, another element such as a passive element including a capacitor or a resistor may be used.

It is apparent that the present invention is not limited to the above embodiment, which may be modified and changed without departing from the scope and spirit of the invention.

What is claimed is:

1. A semiconductor device comprising:
a substrate having bonding pads are formed thereon;
a first element having a plurality of electrodes stacked on said substrate, said first element and said bonding pads being connected to each other by bonding using wires;
a second element stacked on the first element; and
an adhesive layer containing a filler formed between said first element and said second element;
wherein an average grain size of said filler is larger than a distance between said adjacent wires formed on said first element.

2. The semiconductor device as claimed in claim 1,
wherein said adhesive layer is obtained by hardening a paste adhesive agent containing said filler.

3. The semiconductor device as claimed in claim 1,
wherein said adhesive layer is obtained by hardening a sheet-like adhesive agent containing said filler.

4. The semiconductor device as claimed in claim 1, wherein a shape of said filler is almost spherical.

5. The semiconductor device as claimed in claim 1,
wherein an average grain size of said filler is not more than 1.3 times as a distance between said adjacent wires.

6. The semiconductor device as claimed in claim 1,
wherein said first element has said electrodes along an edge of said first element.

7. The semiconductor device as claimed in claim 1, wherein said second element is located immediately above at least some of said plurality of electrodes formed on said first element.
